(19) United States
(12) Patent Application Publication
(10) Pub. No.: US 2023/0411232 A1
(43) Pub. Date: Dec. 21, 2023

(54) SEMICONDUCTOR DEVICE

(71) Applicant: ROHM CO., LTD., Kyoto-shi, Kyoto (JP)

(72) Inventor: Yosui FUTAMURA, Kyoto-shi, Kyoto (JP)

(21) Appl. No.: 18/254,310

(22) PCT Filed: Nov. 1, 2021
(86) PCT No.: PCT/JP2021/040269

§ 371 Date: May 24, 2023

(30) Foreign Application Priority Data
Nov. 30, 2020 (JP) 2020-198250

(51) Int. Cl. H01L 23/31; H01L 23/00; H01L 23/495

(52) U.S. Cl. CPC H01L 23/3142; H01L 24/48; H01L 23/49548; H01L 24/32; H01L 24/73; H01L 23/49513; H01L 2224/32245; H01L 2224/48247; H01L 2224/73265; H01L 2924/18301

(57) ABSTRACT

A semiconductor device includes a conductor, a semiconductor element, and a sealing resin. The conductor includes an obverse surface including a first edge, a reverse surface spaced apart from the obverse surface in a thickness direction and including a second edge, and an intermediate surface connected to the first edge and the second edge. The semiconductor element is supported on the obverse surface. The sealing resin covers the obverse surface, the semiconductor element, and at least a portion of the intermediate surface. The reverse surface of the conductor is exposed from the sealing resin. The first edge is located outward from the second edge as viewed in the thickness direction. In a cross section orthogonal to the first edge, the intermediate surface includes a first point located between the first edge and the second edge and a second point located between the first edge and the first point. The first distance from the obverse surface to the first point in the thickness direction is smaller than the second distance from the obverse surface to the second point in the thickness direction.

### TECHNICAL FIELD

The present disclosure relates to a semiconductor device. In particular, the present disclosure relates to a semiconductor device in which a conductor supporting a semiconductor element is at least partially covered with a sealing resin.

### BACKGROUND ART

Conventionally, semiconductor devices of a resin package type are widely known. A resin-package type semiconductor device includes, for example, a semiconductor element, a conductor supporting the semiconductor element, and a sealing resin covering the conductor. The conductor may be made of a lead frame. An example of such a semiconductor device is disclosed in Patent Document 1.

In the semiconductor device disclosed in Patent Document 1, the periphery of the lead frame (conductor) is half-etched. The sealing resin (molded resin) holds the periphery from both sides in the thickness direction of the lead frame. Thus, even in a configuration in which the reverse surface of the lead frame is exposed from the sealing resin, the lead frame is prevented from falling out of the sealing resin.

In the semiconductor device disclosed in Patent Document 1, separation between the lead frame and the sealing resin may occur on the reverse side of the lead frame. Progress of such separation allows easy intrusion of undesirable external factors (which can cause corrosion of the lead frame or leakage current). Because this may result in defects in the semiconductor device, an effective means of eliminating or reducing such separation is desired.

### PRIOR ART DOCUMENT

### Patent Document

Patent Document 1: 2006-156674

### SUMMARY OF THE INVENTION

### Problem to be Solved by the Invention

In light of the above circumstances, an object of the present disclosure is to provide a semiconductor device capable of effectively eliminating or reducing the separation between the conductor and the sealing resin.

### Means to Solve the Problem

A semiconductor device provided according to the present disclosure includes: a conductor including an obverse surface including a first edge, a reverse surface spaced apart from the obverse surface in a thickness direction and including a second edge, and an intermediate surface connected to the first edge and the second edge; a semiconductor element supported on the obverse surface and electrically connected to the conductor; and a sealing resin that covers the obverse surface, the semiconductor element, and at least a portion of the intermediate surface. The reverse surface of the conductor is exposed from the sealing resin. The first edge is located outward from the second edge as viewed in the thickness direction. In a cross section orthogonal to the first edge, the intermediate surface includes a first point located between the first edge and the second edge and a second point located between the first edge and the first point. The first distance from the obverse surface to the first point in the thickness direction is smaller than the second distance from the obverse surface to the second point in the thickness direction.

### Advantages of the Invention

According to the above-mentioned configuration, the separation between the conductor and the sealing resin is effectively eliminated or reduced.

Other features and advantages of the present disclosure will be more apparent from the detailed description given below with reference to the accompanying drawings.

### BRIEF DESCRIPTION OF THE DRAWINGS

FIG. 1 is a plan view of a semiconductor device according to a first embodiment of the present disclosure as seen through a sealing resin;

FIG. 2 is a bottom view of the semiconductor device shown in FIG. 1;

FIG. 3 is a right side view of the semiconductor device shown in FIG. 1;

FIG. 4 is a front view of the semiconductor device shown in FIG. 1;

FIG. 5 is a sectional view taken along line V-V in FIG. 1;

FIG. 6 is a sectional view taken along line VI-VI in FIG. 1;

FIG. 7 is an enlarged view showing a part of FIG. 6;

FIG. 8 is an enlarged view showing a part of FIG. 6;

FIG. 9 is a sectional view for describing a manufacturing step of the semiconductor device shown in FIG. 1;

FIG. 10 is a sectional view for describing a manufacturing step of the semiconductor device shown in FIG. 1;

FIG. 11 is a sectional view for describing a manufacturing step of the semiconductor device shown in FIG. 1;

FIG. 12 is a sectional view for describing a manufacturing step of the semiconductor device shown in FIG. 1;

FIG. 13 is a sectional view for describing a manufacturing step of the semiconductor device shown in FIG. 1;

FIG. 14 is a sectional view for describing a manufacturing step of the semiconductor device shown in FIG. 1;

FIG. 15 is a sectional view for describing a manufacturing step of the semiconductor device shown in FIG. 1;

FIG. 16 is a sectional view for describing a manufacturing step of the semiconductor device shown in FIG. 1;

FIG. 17 is an enlarged sectional view showing a part of a first variation of the semiconductor device shown in FIG. 1;

FIG. 18 is an enlarged sectional view showing a part of a second variation of the semiconductor device shown in FIG. 1;

FIG. 19 is an enlarged sectional view showing a part of a third variation of the semiconductor device shown in FIG. 1;

FIG. 20 is a plan view of a semiconductor device according to a second embodiment of the present disclosure as seen through a sealing resin;

FIG. 21 is a sectional view taken along line XXI-XXI in FIG. 20;

FIG. 22 is an enlarged sectional view showing a part of a semiconductor device according to a third embodiment of the present disclosure;

FIG. 23 is an enlarged sectional view showing a part of a variation of the semiconductor device shown in FIG. 22;

FIG. 24 is an enlarged sectional view showing a part of a semiconductor device according to a fourth embodiment of the present disclosure;

FIG. 25 is an enlarged sectional view showing a part of a variation of the semiconductor device shown in FIG. 24;

FIG. 26 is a plan view of a semiconductor device according to a fifth embodiment of the present disclosure as seen through a sealing resin;

FIG. 27 is a bottom view of the semiconductor device shown in FIG. 26;

FIG. 28 is a front view of the semiconductor device shown in FIG. 26;

FIG. 29 is a sectional view taken along line XXIX-XXIX in FIG. 26;

FIG. 30 is an enlarged view showing a part of FIG. 29; and

FIG. 31 is an enlarged sectional view showing a part of a variation of the semiconductor device shown in FIG. 26.

### MODE FOR CARRYING OUT THE INVENTION

Preferred embodiments of the present disclosure are described below with reference to the accompanying drawings.

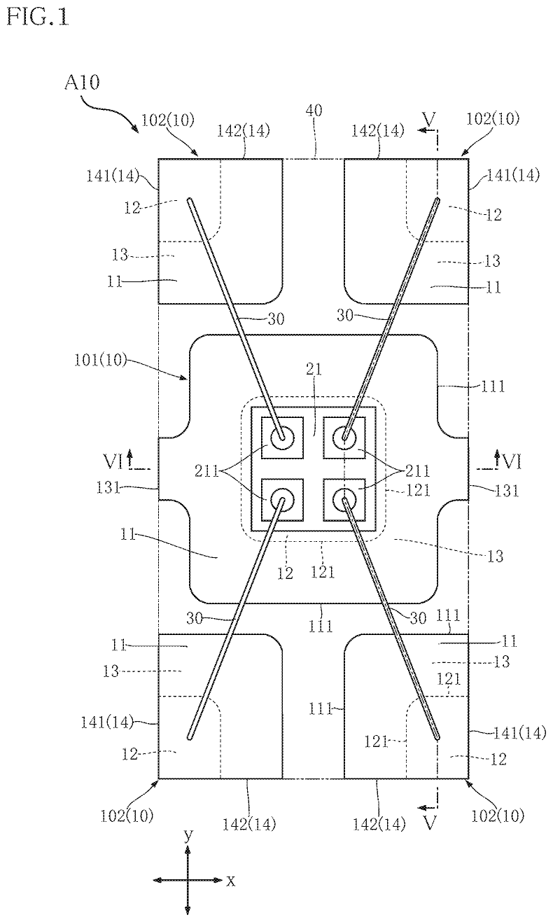

A semiconductor device A10 according to a first embodiment of the present disclosure is described below with reference to FIGS. 1 to 8. The semiconductor device A10 includes a conductor 10, a semiconductor element 21, a plurality of wires 30, and a sealing resin 40. The semiconductor device A10 may be a magnetic sensor (Hall IC) in which the semiconductor element 21 is a Hall element. The semiconductor device A10 is of a resin package type that allows surface-mounting on a wiring board of various electronic devices. The semiconductor element 21 is not limited to a Hall element and may be other types of elements that can be supported on the conductor 10. For convenience of understanding, the sealing resin 40 is shown as transparent in FIG. 1. In FIG. 1, the outline of sealing resin 40 is shown by imaginary lines (two-dot chain lines).

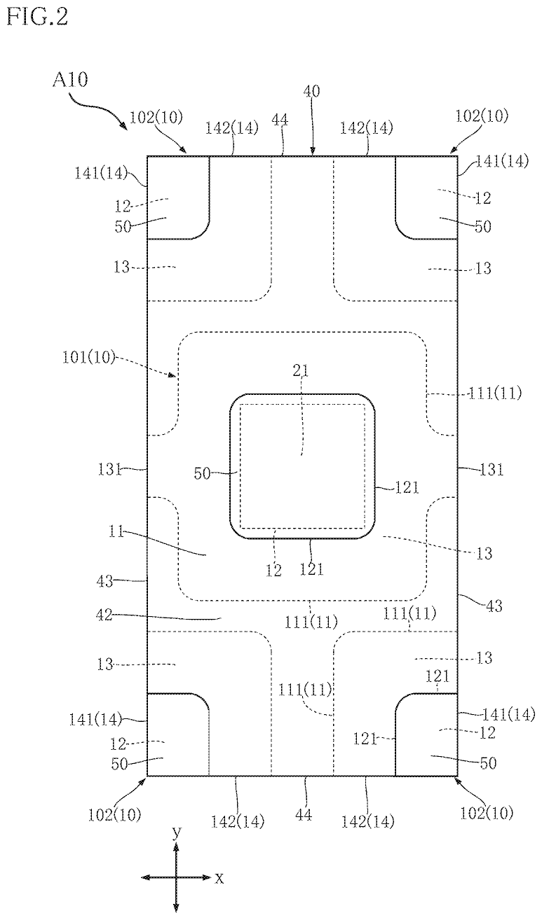

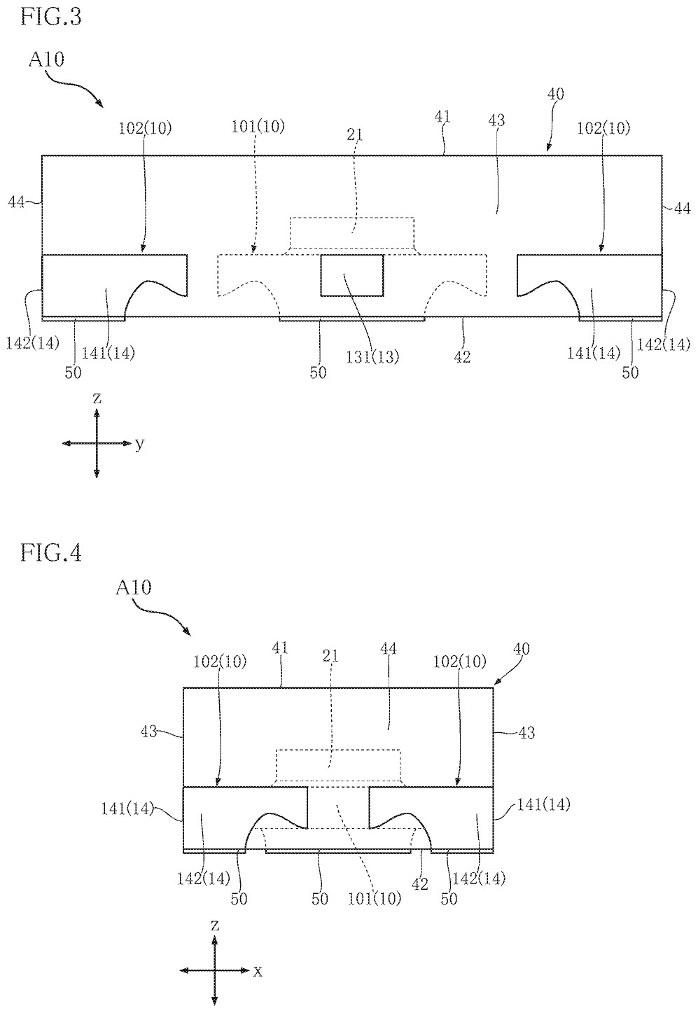

In the description of the semiconductor device A10 (and semiconductor devices A20 to A50 described later), reference will be made to three mutually orthogonal directions (i.e., the direction x, the direction y and the direction z), as appropriate. As shown in FIG. 3, the direction z is the direction orthogonal to the obverse surface (or reverse surface) of the conductor 10 and also referred to as “thickness direction (z)” of the conductor 10 (or semiconductor element 21, etc.). The direction x and the direction y are also referred to as “first direction (x)” and “second direction (y)”, respectively, but the present disclosure is not limited by such definition. As shown in FIGS. 1 and 2, as viewed in the thickness direction z (in plan view), the semiconductor device A10 is in the form of a rectangle with its longer side extending along the second direction y.

As shown in FIGS. 1 to 6, the conductor 10 includes a die pad 101 and a plurality of terminals 102. The die pad 101 supports the semiconductor element 21. The terminals 102 are spaced apart from the die pad 101 and disposed at four corners of the semiconductor device A10 as viewed in the thickness direction z. The number and arrangement of terminals 102 are not limited to this. The terminals 102 are electrically connected to the semiconductor element 21. The conductor 10 (die pad 101 and terminals 102) are made of a metal material. The composition of the metal material includes copper (Cu). In other words, the metal material contains copper. The metal material is not limited to a material containing copper and may be other non-magnetic materials.

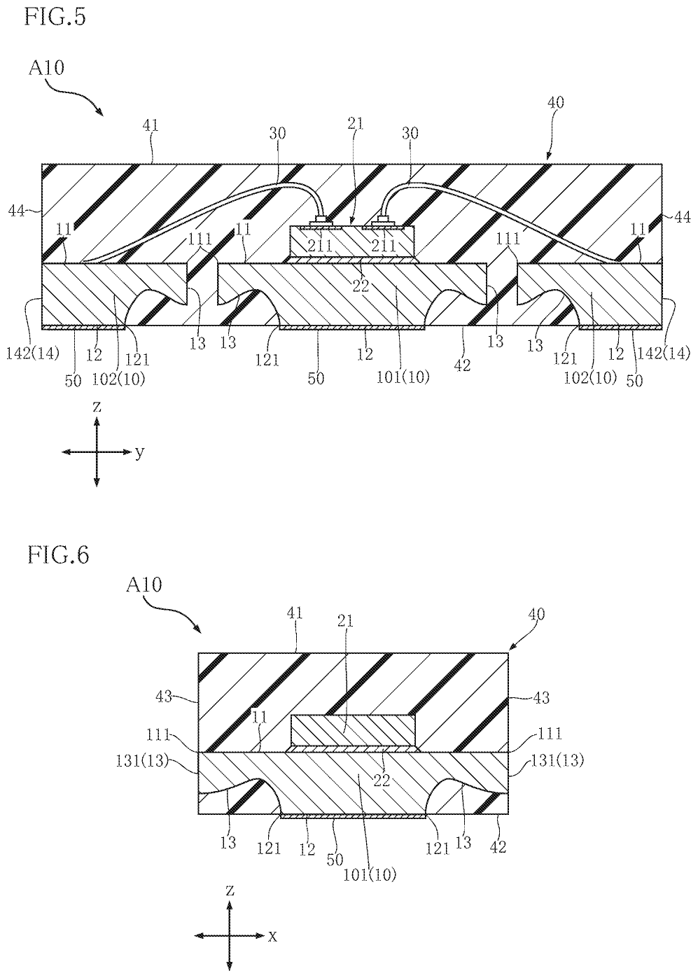

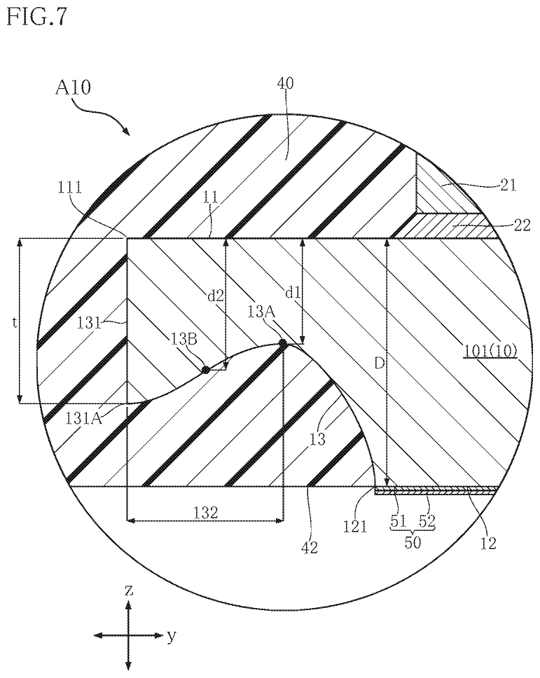

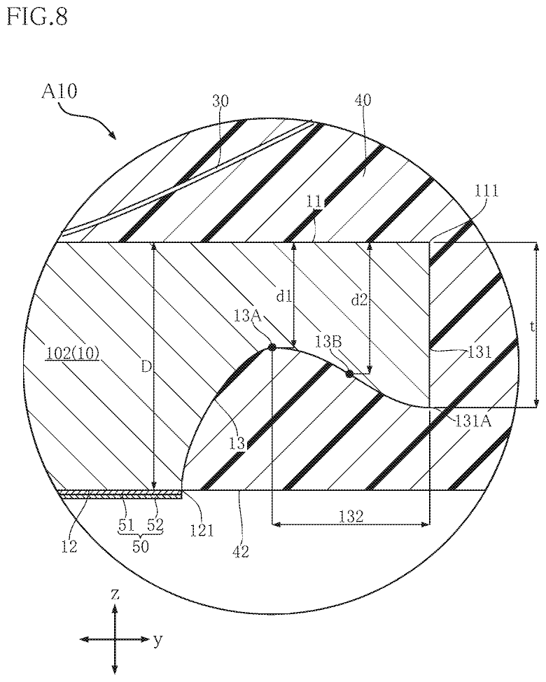

As shown in FIGS. 5 and 6, the conductor 10 has an obverse surface 11 and a reverse surface 12 (see also FIGS. 1 and 2). In the illustrated example, the obverse surface 11 is an aggregation of a plurality of regions (e.g., flat regions). (This holds for the reverse surface 12.) The obverse surface 11 faces a first side in the thickness direction z. The obverse surface 11 has a first edge 111. In the illustrated example, the first edge 111 refers to a plurality of sections (straight-line segments) included in the perimeter of the obverse surface 11, and each section extends in either the first direction x or the second direction y. The reverse surface 12 faces a second side in the thickness direction z. The reverse surface 12 is exposed from the sealing resin 40. In the illustrated example, the reverse surface 12 is flush with a bottom surface (the bottom surface 42 described later) of the sealing resin 40 and is not covered with the sealing resin 40. The reverse surface 12 has a second edge 121. In the illustrated example, the second edge 121 refers to a plurality of sections (straight-line segments) included in the perimeter of the reverse surface 12, and each section extends in either the first direction x or the second direction y. In the die pad 101, the first edge 111 is located outward from the second edge 121, as viewed in the thickness direction z (see FIGS. 1 and 2). (In other words, the first edge 111 is located farther away from the center of the reverse 12 of the die pad 101 than is the second edge 121.) Also in each terminal 102, the first edge 111 is located outward from the second edge 121. (In other words, the first edge 111 is located farther away from the center of the reverse 12 of the terminal 102 than is the second edge 121.) Thus, in the die pad 101 and each of the terminals 102, the reverse surface 12 entirely overlaps with the obverse surface 11, and the area of the reverse surface 12 is smaller than that of the obverse surface 11. As shown in FIGS. 7 and 8, the die pad 101 and each terminal 102 are equal to each other in the distance D from the obverse surface 11 to the reverse surface 12 in the thickness direction z. That is, the die pad 101 and each terminal 102 are equal to each other in the maximum thickness (distance D).

The obverse surface 11 of the conductor 10 may be formed with a metal plating layer. The composition of the metal plating layer may include silver (Ag), for example. Alternatively, the composition of the metal plating layer may include nickel (Ni) and palladium (Pd) or may include nickel, palladium, and gold (Au).

As shown in FIGS. 1, 2, 5 and 6, the conductor 10 has at least one intermediate surface 13. In the illustrated example, the die pad 101 and the terminals 102 each have an intermediate surface 13. In the die pad 101, the intermediate surface 13 is connected to the first edge 111 of the obverse surface 11 and the second edge 121 of the reverse surface 12. (This holds for each terminal 102.) As shown in FIGS. 7 and 8, in a cross section orthogonal to the direction in which the first edge 111 extends, the intermediate surface 13 (or more precisely, the outline of the intermediate surface 13 in the cross section) includes a first point 13A and a second point 13B. In the cross section, the first point 13A is located between the first edge 111 and the second edge 121. In the cross section, the second point 13B is located between the first edge 111 and the first point 13A. The first distance d1 from the obverse surface 11 to the first point 13A in the thickness direction z is smaller than the second distance d2 from the obverse surface 11 to the second point 13B in the thickness direction z. Under these conditions, supposing that a hypothetical plane containing the first point 13A and orthogonal to the thickness direction z is given, a portion of the section of the intermediate surface 13 which extends from the first edge 111 to the first point 13A is located under the hypothetical plane (i.e., offset from the hypothetical plane toward the second side in the thickness direction z).

As shown in FIGS. 7 and 8, the intermediate surface 13 includes an end (end-surface part) 131 and an overhang (overhang-surface part) 132. The end 131 extends from the first edge 111 of the obverse surface 11 toward the second side in the thickness direction z. The end 131 has a lower edge (edge 131A or “third edge”) and an upper edge that are spaced apart from each other in the thickness direction z. The overhang 132 extends from the edge 131A to the first point 13A of the intermediate surface 13. In the semiconductor device A10, the second point 13B of the intermediate surface 13 is included in the overhang 132. In the present disclosure, the second point 13B may be any point that is located between the first edge 111 and the first point 13A of the intermediate surface 13 and satisfies the condition that the second distance d2 is greater than the first distance d1. For example, unlike the example shown in FIGS. 7 and 8, the second point 13B may coincide with the edge 131A.

As shown in FIGS. 7 and 8, the dimension t of the end 131 in the thickness direction z is smaller than the distance D from the obverse surface 11 to the reverse surface 12 of the conductor 10 in the thickness direction z. Thus, except some portions of the ends 131 of the die pad 101 (see e.g., FIG. 6), the intermediate surface 13 is covered substantially with the sealing resin 40. The dimension t of the end 131 in the thickness direction z is equal to or greater than the second distance d2 from the obverse surface 11 to the second point 13B of the intermediate surface 13 (t≥d2).

As shown in FIGS. 1 to 4, each of the terminals 102 has side surfaces 14. The side surfaces 14 face in a direction orthogonal to the thickness direction z and are connected to the obverse surface 11 and the reverse surface 12. The side surfaces 14 are exposed from the sealing resin 40. The side surfaces 14 include a first surface 141 and a second surface 142. The first surface 141 faces in the first direction x. The second surface 142 faces in the second direction y and is connected to the first surface 141.

As shown in FIGS. 1, 5 and 6, the semiconductor element 21 is supported on the die pad 101. The semiconductor element 21 is rectangular as viewed in the thickness direction z. The semiconductor element 21 may be a Hall element that uses gallium arsenide (GaAs) as the material, for example. The Hall element has the advantages that the Hall voltage has excellent linearity with respect to changes in the magnetic flux density and it is less susceptible to temperature changes. The semiconductor element 21 may be a Hall element that uses one of silicon (Si), indium arsenide (InAs), and indium antimonide (InSb), as the material. As shown in FIGS. 1 and 5, the semiconductor element 21 has a plurality of electrodes 211. The electrodes 211 are on the first side of the semiconductor element 21 in the thickness direction z. The electrodes 211 are electrically connected to a circuit formed in the semiconductor element 21. As shown in FIGS. 5 and 6, the semiconductor element 21 is supported, on its second side in the thickness direction z, on the obverse surface 11 of the die pad 101 via a bonding layer 22. The bonding layer 22 is die-attach paste containing metal particles such as silver particles and a synthetic resin.

As shown in FIGS. 1 and 5, the wires 30 are bonded to the electrodes 211 of the semiconductor element 21 and the obverse surfaces 11 of the terminals 102. Thus, the terminals 102 are electrically connected to the semiconductor element 21. The composition of the wires 30 may include gold, for example.

As shown in FIGS. 5 and 6, the sealing resin 40 covers the obverse surface 11 of the conductor 10, the semiconductor element 21, the wires 30, and at least portions of the intermediate surface 13 of the conductor 10. The sealing resin 40 is electrically insulating. The sealing resin 40 is made of a material containing a thermosetting synthetic resin. The synthetic resin may be black epoxy resin.

As shown in FIGS. 3 to 6, the sealing resin 40 has a top surface 41, a bottom surface 42, a pair of first side surfaces 43, and a pair of second side surfaces 44. The top surface 41 faces the first side in the thickness direction z. The bottom surface 42 faces the second side in the thickness direction z. The reverse surface 12 of the conductor 10 is exposed at the bottom surface 42. The bottom surface 42 is flush with the reverse surface 12.

As shown in FIGS. 2 to 4 and 6, the paired first side surfaces 43 face away from each other in the first direction x and are connected to the top surface 41 and the bottom surface 42. The first surfaces 141 of the terminals 102 and some portions of the ends 131 of the die pad 101 are exposed at the first side surfaces 43. The portions exposed at the first side surfaces 43 are flush with the first side surfaces 43.

As shown in FIGS. 2 to 5, the paired second side surfaces 44 face away from each other in the second direction y and are connected to the top surface 41, the bottom surface 42, and the paired first side surfaces 43. The second surfaces 142 of the terminals 102 are exposed at the second side surfaces 44. The second surfaces 142 of the terminal 102 are flush with the second side surfaces 44.

As shown in FIGS. 2, 5 and 6, the reverse surface 12 of the conductor 10 is covered with a coating layer 50. The coating layer 50 contains a metallic element. The metallic element includes at least one of nickel and palladium. As shown in FIGS. 7 and 8, the coating layer 50 includes a first layer 51 and a second layer 52. The first layer 51 covers the reverse surface 12. The composition of the first layer 51 includes nickel. The second layer 52 is on the first layer 51. The composition of the second layer 52 includes palladium. In this way, in the semiconductor device A10, the coating layer 50 includes a plurality of metal layers laminated in the thickness direction z. Alternatively, the coating layer 50 may be a single metal layer. In such a case, the composition of the metal layer include one of nickel and palladium.

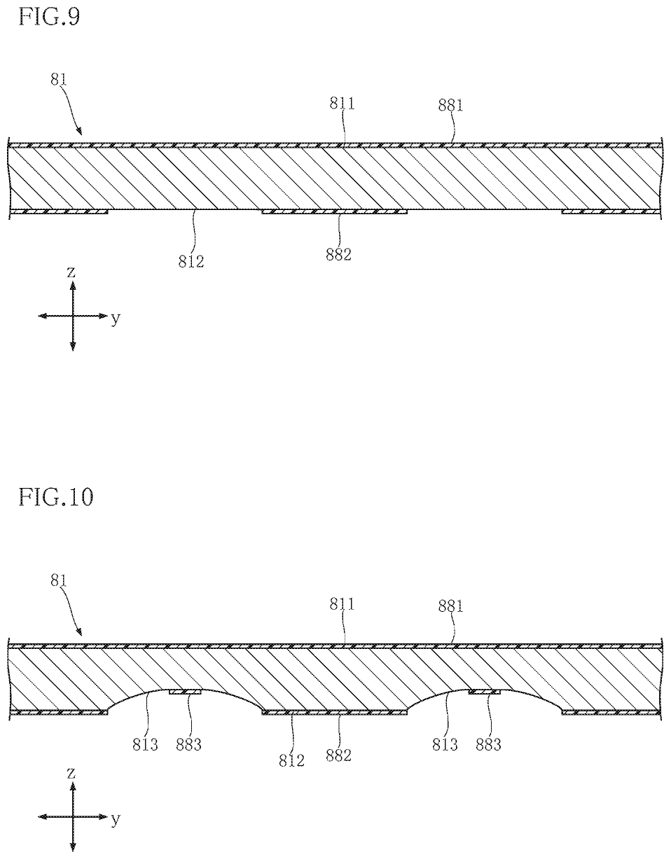

An example of a method for manufacturing the semiconductor device A10 is described below with reference to FIGS. 9 to 16. Note that FIGS. 9 to 16 are sectional views that can be compared to the view of FIG. 5, which shows the semiconductor device A10.

As shown in FIG. 9, on a substrate 81 having an obverse surface 811 and a reverse surface 812 facing away from each other in the thickness direction z, a first mask layer 881 that covers the entirety of the obverse surface 811 and a second mask layer 882 that covers portions of the reverse surface 812 are formed. The substrate 81 is a thin metal plate that includes, for example, copper in its composition. The thickness of the substrate 81 is, for example, 100 μm. A portion of the substrate 81 corresponds to the conductor 10 of a semiconductor device A10. Each of the obverse surface 811 and the reverse surface 812 is a uniform flat surface. The first mask layer 881 is formed by applying a resist solution for photolithography to the obverse surface 811. The second mask layer 882 is formed by photolithographic patterning.

As shown in FIG. 10, first wet etching is performed to remove portions of the substrate 81. As the etchant, a mixed solution of H₂SO₄ (sulfuric acid) and H₂O₂ (hydrogen peroxide) may be used. By removing portions of the substrate 81 in this process, first concave surfaces 813 recessed from the reverse surface 812 in the thickness direction z are formed in the substrate 81. Thereafter, a third mask layer 883 is formed to cover portions of the first concave surfaces 813 that are closest to the obverse surface 811. The third mask layer 883 is formed by photolithographic patterning.

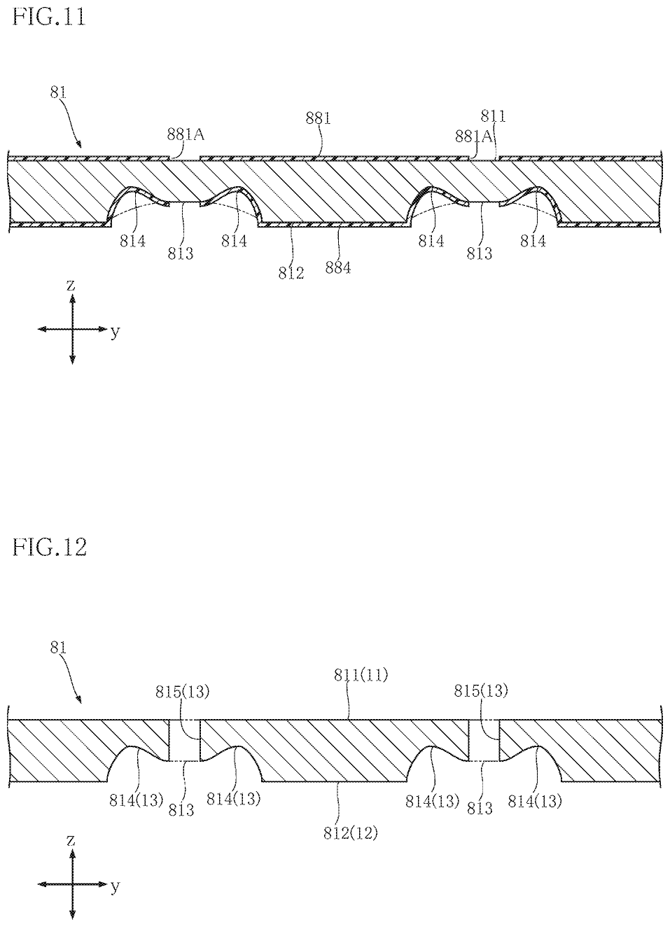

As shown in FIG. 11, second wet etching is performed to remove portions of the substrate 81. By removing portions of the substrate 81 in this process, second concave surfaces 814 recessed from the first concave surfaces 813 in the thickness direction z are formed in the substrate 81. Next, after the second mask layer 882 and the third mask layer 883 are removed, a fourth mask layer 884 is formed to entirely cover the reverse surface 812 and each of the second concave surfaces 814. The fourth mask layer 884 is formed by photolithographic patterning. Thereafter, photolithographic patterning is performed to form openings 881A in the first mask layer 881, thereby exposing, from the first mask layer 881, the regions of the obverse surface 811 that overlap with the first concave surfaces 813 as viewed in thickness direction z.

As shown in FIG. 12, third wet etching is performed to remove portions of the substrate 81. This partial removal of the substrate 81 is performed from both sides of the substrate 81 in the thickness direction z. By removing portions of the substrate 81 in this process, end surfaces 815 are formed in the substrate 81 that face in a direction orthogonal to the thickness direction z and are connected to the obverse surface 811 and the second concave surfaces 814. Thereafter, the first mask layer 881 and the fourth mask layer 884 are removed. Through this process, the obverse surface 811 becomes the obverse surface 11 of the conductor 10, and the reverse surface 812 becomes the reverse surface 12 of the conductor 10. The second concave surfaces 814 and the end surfaces 815 become the intermediate surface 13 of the conductor 10.

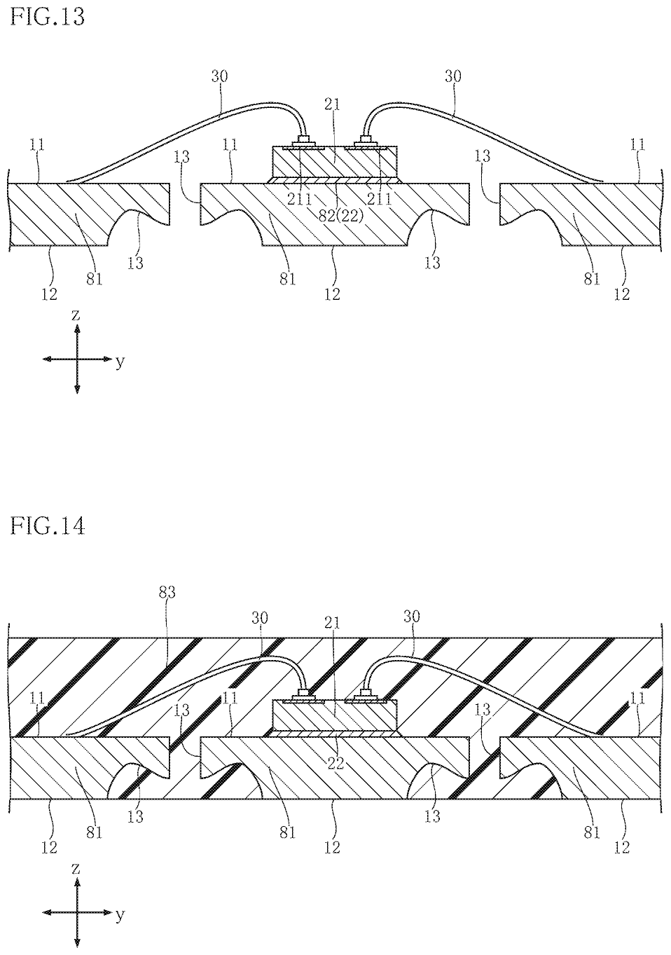

Next, a semiconductor element 21 is supported on the substrate 81, as shown in FIG. 13. To support the semiconductor element 21 on the substrate, a bonding material 82 is first applied to the obverse surface 811 of the substrate 81. The bonding material 82 may be a conductive paste containing silver, for example. Next, after the semiconductor element 21 sucked by e.g. a collet is transferred on top of the substrate 81, the semiconductor element 21 is bonded to the bonding material 82. Finally, the bonding material 82 is heat-cured in a curing furnace, for example. The heat-cured bonding material 82 corresponds to the bonding layer 22 of the semiconductor device A10. Thereafter, a plurality of wires 30 bonded to the semiconductor element 21 and the substrate 81 are formed through a wire bonding process.

As shown in FIG. 14, a sealing resin 83 is formed to cover the semiconductor element 21, the wires 30, and portions of the substrate 81. The sealing resin 83 is formed by heat-curing a thermosetting synthetic resin having electrical insulation properties by transfer molding. Through this process, the obverse surface 11 and the intermediate surface 13 of the substrate 81 are covered with the sealing resin 83, with the reverse surface 12 of the substrate 81 exposed from the sealing resin 83.

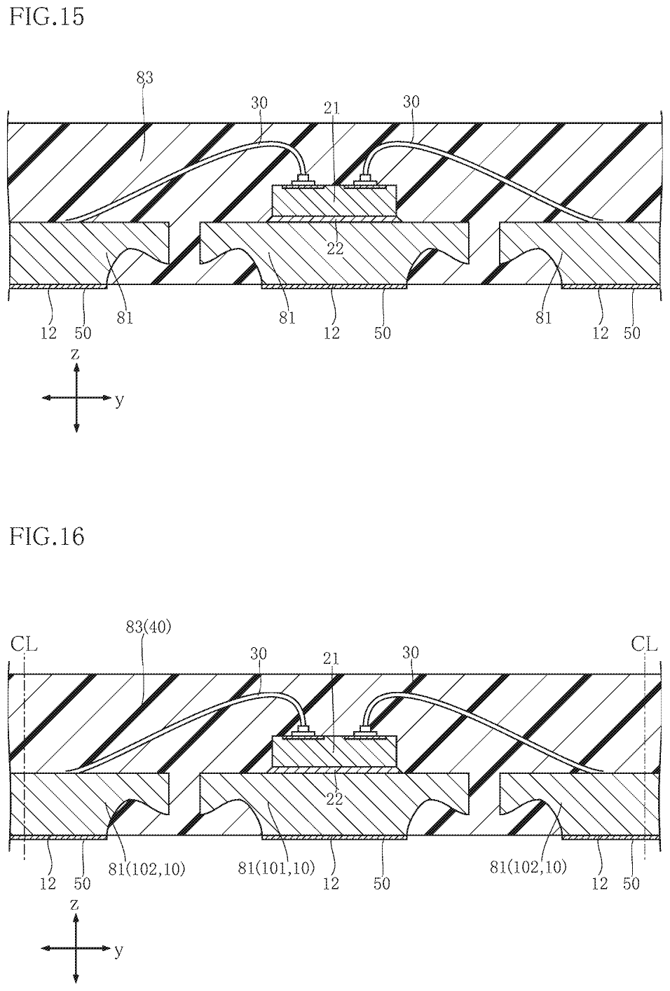

As shown in FIG. 15, a coating layer 50 that covers the reverse surface 812 of the substrate 81 is formed. The coating layer 50 is formed by electrolytic plating using the substrate 81 as the conduction path.

As shown in FIG. 16, the substrate 81 (including the coating layer 50) and the sealing resin 83 are cut along the first direction x and the second direction y for division into individual pieces each having one semiconductor element 21. In this cutting process, the substrate 81 is cut from the reverse surface 12 in the thickness direction z by using a dicing saw, for example. In cutting along the first direction x, the substrate is cut along the cutting line CL shown in FIG. 16. Each individual piece provided by this dividing process is a semiconductor device A10. By this process, the substrate 81 becomes the conductor 10 of the semiconductor device A10 which includes a die pad 101 and terminals 102. The sealing resin 83 becomes the sealing resin 40 of the semiconductor device A10. In this way, the semiconductor device A10 is obtained.

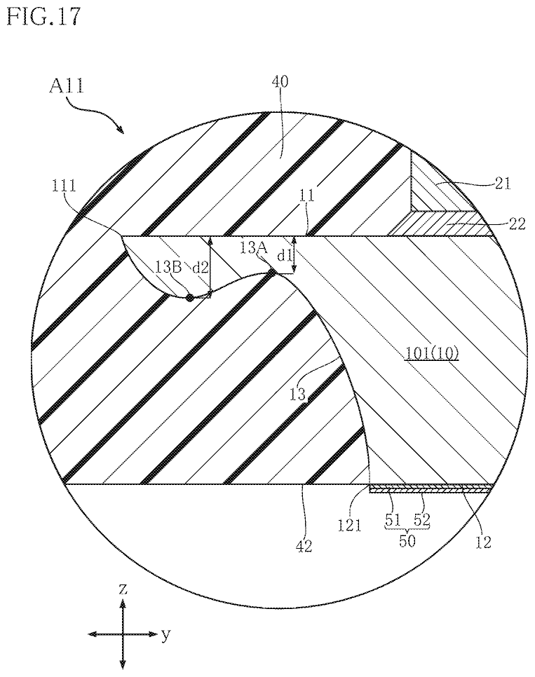

A semiconductor device A11 as a first variation of the semiconductor device A10 is described below with reference to FIG. 17. Note that FIG. 17 is a sectional view that can be compared to the view of FIG. 7, which shows the semiconductor device A10.

As shown in FIG. 17, the semiconductor device A11 differs from the semiconductor device A10 in configuration of the intermediate surface 13 of the conductor 10. In the semiconductor device A11, the intermediate surface 13 does not include a distinct end 131 and a distinct overhang 132. In a cross section orthogonal to the direction in which the first edge 111 of the obverse surface 11 extends, the portion of the conductor 10 defined by the obverse surface 11 and the section of the intermediate surface 13 from the first edge 111 to the first point 13A has an average thickness smaller than that of the corresponding portion of the semiconductor device A10. The semiconductor device A11 also satisfies the relationship that the first distance d1 from the obverse surface 11 to the first point 13A of the intermediate surface 13 in the thickness direction z is smaller than the second distance d2 from the obverse surface 11 to the second point 13B of the intermediate surface 13 in the thickness direction z.

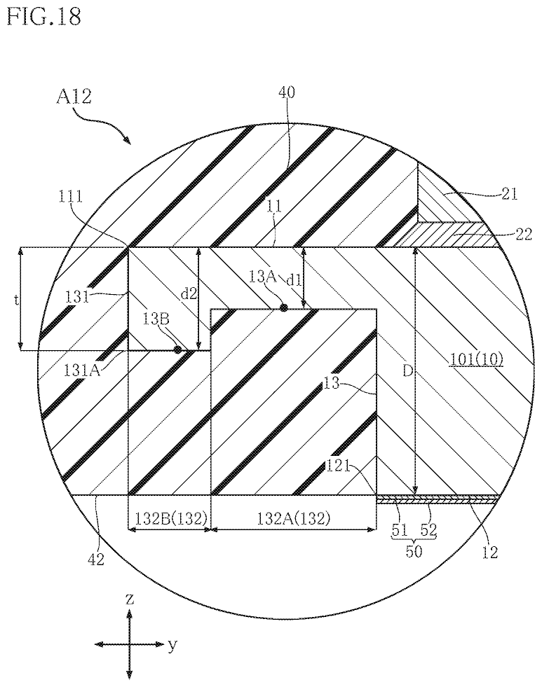

A semiconductor device A12 as a second variation of the semiconductor device A10 is described below with reference to FIG. 18. Note that FIG. 18 is a sectional view that can be compared to the view of FIG. 7, which shows the semiconductor device A10.

As shown in FIG. 18, the semiconductor device A12 differs from the semiconductor device A10 in configuration of the intermediate surface 13 of the conductor 10. In the semiconductor device A12, the overhang 132 of the intermediate surface 13 includes a first region 132A and a second region 132B. Both of the first region 132A and the second region 132B are flat surfaces facing the second side in the thickness direction z. As viewed in the thickness direction z, the second region 132B is located between the first edge 111 of the obverse surface 11 and the first region 132A. In the thickness direction z, the first region 132A is located between the obverse surface 11 and the second region 132B. The first point 13A of the intermediate surface 13 is included in the first region 132A. The first point 13A may be at any position within the first region 132A. The second point 13B of the intermediate surface 13 is included in the second region 132B. The second point 13B may be at any position within the second region 132B. The semiconductor device A12 having such a configuration also satisfies the relationship that the first distance d1 from the obverse surface 11 to the first point 13A in the thickness direction z is smaller than the second distance d2 from the obverse surface 11 to the second point 13B in the thickness direction z.

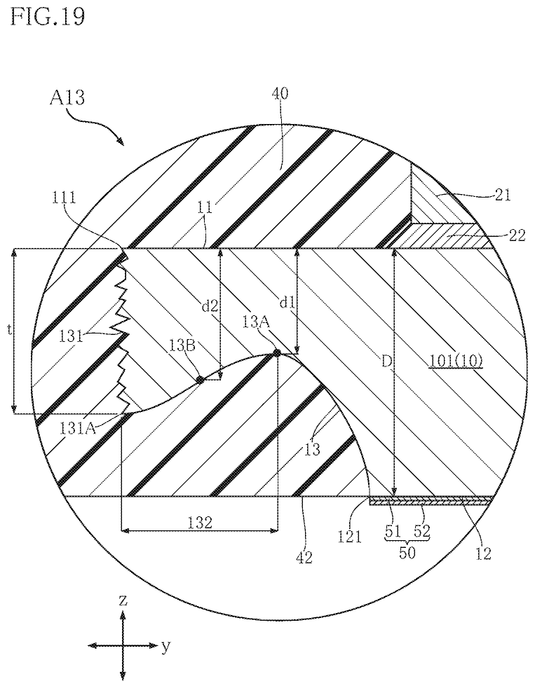

A semiconductor device A13 as a third variation of the semiconductor device A10 is described below with reference to FIG. 19. Note that FIG. 19 is a sectional view that can be compared to the view of FIG. 7, which shows the semiconductor device A10.

As shown in FIG. 19, the semiconductor device A13 differs from the semiconductor device A10 in configuration of the intermediate surface 13 of the conductor 10. In the semiconductor device A13, the surface roughness of the end 131 of the intermediate surface 13 is greater than that of the overhang 132 of the intermediate surface 13. Such a configuration is obtained by roughening the end surface 815 of the substrate 81 by application of a chemical solution during the manufacturing process of the semiconductor device A10 shown in FIG. 12. As the chemical solution, either an acidic solution or an alkaline solution is selected. An example of acidic solution is a mixed solution of sulfuric acid and hydrogen peroxide. An example of alkaline solution is an aqueous solution of ammonium formate (NH₄HCO₂).

The effects and advantages of the semiconductor device A10 are described below.

The semiconductor device A10 includes a conductor 10 that has an obverse surface 11 including a first edge 111, a reverse surface 12 including a second edge 121 and exposed from the sealing resin 40, and an intermediate surface 13 connected to the first edge 111 and the second edge 121. As viewed in the thickness direction z, the first edge 111 is located outward from the second edge 121. In a cross section orthogonal to the direction in which the first edge 111 of the obverse surface 11 extends, the intermediate surface 13 includes a first point 13A located between the first edge 111 and the second edge 121, and a second point 13B located between the first edge 111 and the first point 13A. The first distance d1 from the obverse surface 11 to the first point 13A in the thickness direction z is smaller than the second distance d2 from the obverse surface 11 to the second point 13B in the thickness direction z. With such a configuration, in a cross section orthogonal to the direction in which the first edge 111 extends, the intermediate surface 13 includes a section that extends toward the second side in the thickness direction z between the first point 13A and the first edge 111.

In the semiconductor device A10 having such a configuration, when separation between the intermediate surface 13 and the sealing resin 40 occurs from the second edge 121, progress of the separation is inhibited by the region between the first point 13A and the second point 13B of the intermediate surface 13 (separation inhibiting region). Thus, in the semiconductor device A10, the separation does not easily reach the edge 131A, which is the boundary between the end 131 and the overhang 132 as shown in FIG. 7. Thus, the semiconductor device A10 effectively eliminates or reduces the separation between the conductor 10 and the sealing resin 40.

The intermediate surface 13 of the conductor 10 includes the end 131 extending from the first edge 111 of the obverse surface 11 toward the second side in the thickness direction z, and the overhang 132 extending from the edge 131A of the end 131 to the first point 13A. As shown in FIG. 7, the dimension t of the end 131 in the thickness direction z is equal to or greater than the second distance d2 from the obverse surface 11 to the second point 13B in the thickness direction z. With such a configuration, in a cross section orthogonal to the direction in which the first edge 111 extends, the section that extends toward the second side in the thickness direction z between the first point 13A and the first edge 111 is relatively long. This contributes to effective elimination or reduction of the separation between the conductor 10 and the sealing resin 40.

In the semiconductor device A10, the dimension t of the end 131 of the intermediate surface 13 in the thickness direction z is smaller than the distance D from the obverse surface 11 to the reverse surface 12 in the thickness direction z, as shown in FIG. 7. The entire (or substantially the entire) intermediate surface 13 is covered with the sealing resin 40. This contributes to the improvement of the dielectric strength of the semiconductor device A10.

The semiconductor devices A11 to A13, which are the variations of the semiconductor device A10, also satisfy the relationship that the first distance d1 from the obverse surface 11 to the first point 13A of the intermediate surface 13 in the thickness direction z is smaller than the second distance d2 from the obverse surface 11 to the second point 13B of the intermediate surface 13 in the thickness direction z. Because the intermediate surface 13 is configured to satisfy such a relationship, these variations also effectively eliminate or reduce the separation between the conductor 10 and the sealing resin 40, although the configuration of the intermediate surface 13 of the conductor 10 is different.

In the semiconductor device A13, the surface roughness of the end 131 of the intermediate surface 13 is greater than that of the overhang 132 of the intermediate surface 13. Such a configuration increases the surface area of the end 131 and also increases the distance along the surface, or creepage distance, of the end 131 from the edge 131A of the end 131 to the first edge 111 of the obverse surface 11. This contributes to effective elimination or reduction of the separation between the conductor 10 and the sealing resin 40.

The conductor 10 includes a die pad 101 that supports the semiconductor element 21 and terminals 102 electrically connected to the semiconductor element 21. Each terminal 102 has a side surface 14 facing in a direction orthogonal to the thickness direction z and connected to the obverse surface 11 and the reverse surface 12. The side surfaces 14 are exposed from the sealing resin 40. Thus, in mounting the semiconductor device A10 to a circuit board, a solder fillet can be formed on the side surfaces 14. This improves the mounting strength of the semiconductor device A10 to the wiring board.

The semiconductor device A10 further includes a coating layer 50 that covers the reverse surface 12 of the conductor 10. The coating layer 50 contains metallic elements. With such a configuration, during the mounting of the semiconductor device A10 to a circuit board, wettability of solder onto the conductor 10 is improved, while the conductor 10 is reliably protected from thermal shock caused by the solder. In order for such effects to be fully exerted, it is preferable that the metallic elements contained in the coating layer 50 include at least one of nickel and palladium. As an example of the coating layer 50 that can fully exert the above-mentioned effects is a coating layer 50 that includes a first layer 51 covering the reverse surface 12 and including nickel in its composition and a second layer 52 laminated on the first layer 51 and including palladium in its composition, like the coating layer of the semiconductor device A10.

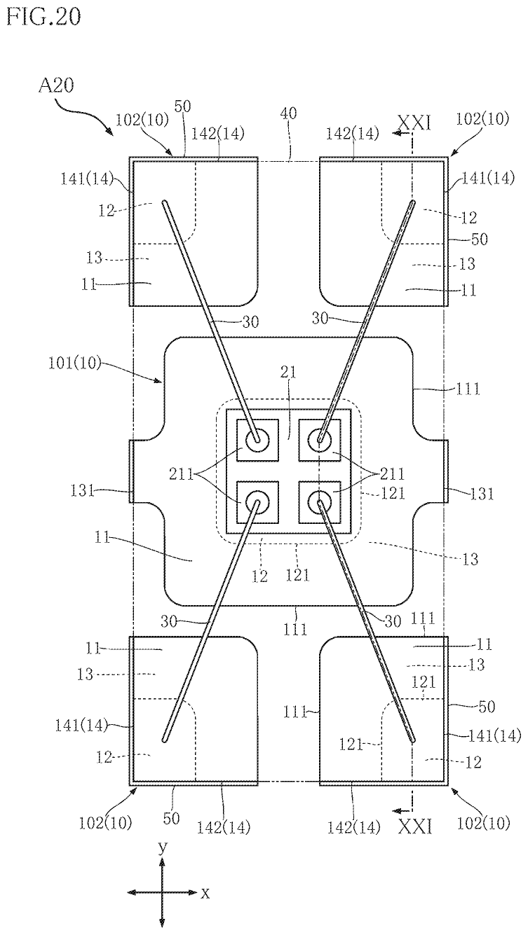

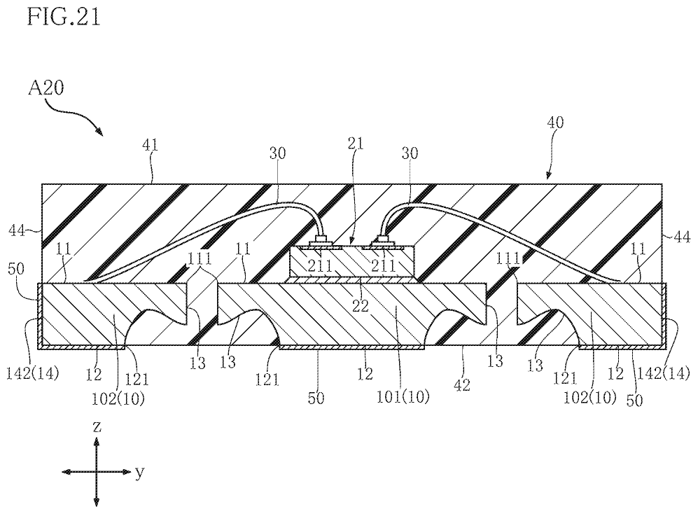

A semiconductor device A20 according to a second embodiment of the present disclosure is described below with reference to FIGS. 20 to 21. In these figures, the elements that are identical or similar to those of the semiconductor device A10 described above are denoted by the same reference signs, and the descriptions thereof are omitted. For convenience of understanding, the sealing resin 40 is shown as transparent in FIG. 20. In FIG. 20, the outline of the sealing resin 40 is shown by imaginary lines (two-dot chain lines).

The semiconductor device A20 differs from the semiconductor device A10 in configuration of the coating layer 50.

As shown in FIGS. 20 and 21, the coating layer 50 covers some of the ends 131 of the die pad 101 and the side surfaces 14 (first surfaces 141 and second surfaces 142) of the terminals 102 in addition to the reverse surface 12 of the conductor 10. The coating layer 50 of the semiconductor device A20 is obtained by the following process. After the processes shown in FIGS. 9 to 14 in the manufacture of the semiconductor device A10, the substrate 81 and the sealing resin 83 are cut into individual pieces, as shown in FIG. 16. Thereafter, electroless plating is performed to form a metal layer that covers the exposed surfaces of the individual pieces obtained from the substrate 81, whereby the coating layer 50 is provided.

The effects and advantages of the semiconductor device A20 are described below.

The semiconductor device A20 includes a conductor 10 that has an obverse surface 11 including a first edge 111, a reverse surface 12 including a second edge 121 and exposed from the sealing resin 40, and an intermediate surface 13 connected to the first edge 111 and the second edge 121. As viewed in the thickness direction z, the first edge 111 is located outward from the second edge 121. In a cross section orthogonal to the direction in which the first edge 111 of the obverse surface 11 extends, the intermediate surface 13 includes a first point 13A located between the first edge 111 and the second edge 121, and a second point 13B located between the first edge 111 and the first point 13A. The first distance d1 from the obverse surface 11 to the first point 13A in the thickness direction z is smaller than the second distance d2 from the obverse surface 11 to the second point 13B in the thickness direction z. Thus, the semiconductor device A20 also effectively eliminates or reduces the separation between the conductor 10 and the sealing resin 40.

In the semiconductor device A20, the coating layer 50 covers the side surfaces 14 of the terminals 102. This improves wettability of solder onto the side surfaces 14. Thus, in mounting the semiconductor device A10 to a wiring board, formation of solder fillet on the side surfaces 14 is promoted. This contributes to further improvement of the mounting strength of the semiconductor device A10 onto the wiring board.

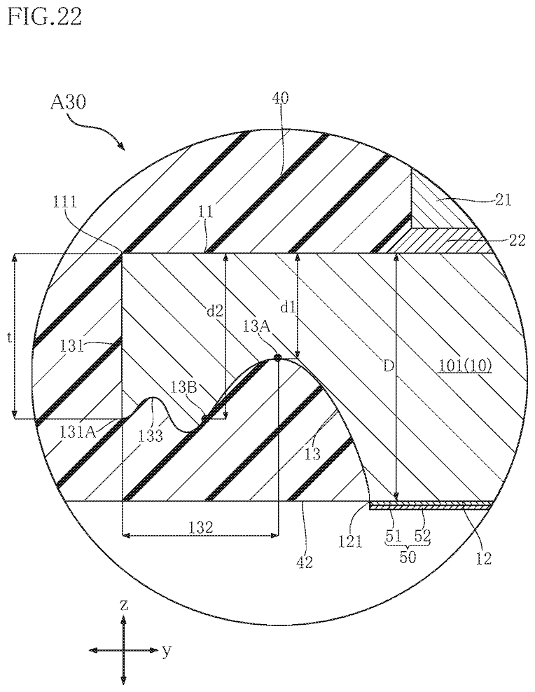

A semiconductor device A30 according to a third embodiment of the present disclosure is described below with reference to FIG. 22. In these figures, the elements that are identical or similar to those of the semiconductor device A10 described above are denoted by the same reference signs, and the descriptions thereof are omitted. Note that FIG. 22 is a sectional view that can be compared to the view of FIG. 7, which shows the semiconductor device A10.

The semiconductor device A30 differs from the semiconductor device A10 in configuration of the intermediate surface 13 of the conductor 10.

As shown in FIG. 22, the intermediate surface 13 includes a recess 133. The recess 133 is recessed toward the first side in the thickness direction z. In the semiconductor device A30, the recess 133 forms a portion of the overhang 132 of the intermediate surface 13. The recess 133 is located between the first edge 111 of the obverse surface 11 and the first point 13A of the intermediate surface 13, as viewed in the thickness direction z.

Referring to FIG. 22, in the semiconductor device A30, the dimension t of the end 131 of the intermediate surface 13 in the thickness direction z may be smaller than the second distance d2 from the obverse surface 11 to the second point 13B of the intermediate surface 13 in the thickness direction z. Alternatively, the dimension t of the end 131 in the thickness direction z may be equal to or greater than the second distance d2.

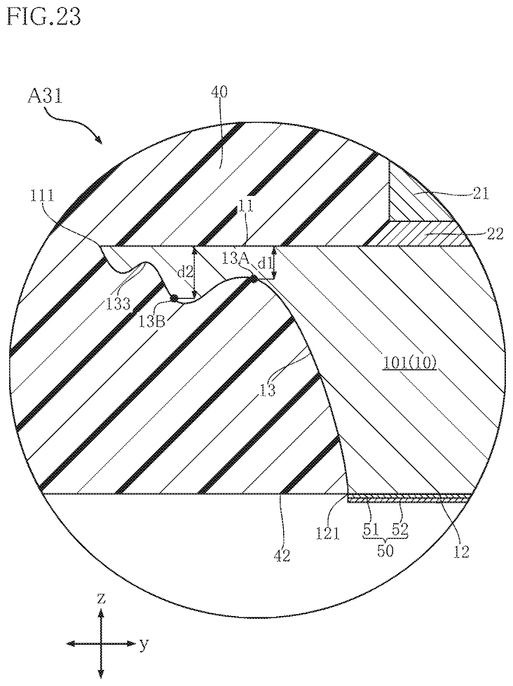

A semiconductor device A31 as a variation of the semiconductor device A30 is described below with reference to FIG. 23. Note that FIG. 23 is a sectional view that can be compared to the view of FIG. 22, which shows the semiconductor device A30.

As shown in FIG. 23, the semiconductor device A31 differs from the semiconductor device A30 in configuration of the intermediate surface 13 of the conductor 10. In the semiconductor device A31, the intermediate surface 13 does not include a distinct end 131 and a distinct overhang 132, while including a recess 133. In a cross section orthogonal to the direction in which the first edge 111 of the obverse surface 11 extends, the portion of the conductor 10 defined by the obverse surface 11 and the section of the intermediate surface 13 from the first edge 111 to the first point 13A has an average thickness smaller than that of the corresponding portion of the semiconductor device A30. The semiconductor device A31 also satisfies the relationship that the first distance d1 from the obverse surface 11 to the first point 13A of the intermediate surface 13 in the thickness direction z is smaller than the second distance d2 from the obverse surface 11 to the second point 13B of the intermediate surface 13 in the thickness direction z.

The effects and advantages of the semiconductor device A30 are described below.

The semiconductor device A30 includes a conductor 10 that has an obverse surface 11 including a first edge 111, a reverse surface 12 including a second edge 121 and exposed from the sealing resin 40, and an intermediate surface 13 connected to the first edge 111 and the second edge 121. As viewed in the thickness direction z, the first edge 111 is located outward from the second edge 121. In a cross section orthogonal to the direction in which the first edge 111 of the obverse surface 11 extends, the intermediate surface 13 includes a first point 13A located between the first edge 111 and the second edge 121, and a second point 13B located between the first edge 111 and the first point 13A. The first distance d1 from the obverse surface 11 to the first point 13A in the thickness direction z is smaller than the second distance d2 from the obverse surface 11 to the second point 13B in the thickness direction z. Thus, the semiconductor device A30 also effectively eliminates or reduces the separation between the conductor 10 and the sealing resin 40.

In the semiconductor device A30, the intermediate surface 13 of the conductor 10 includes a recess 133 that is recessed toward the first side in the thickness direction z. The recess 133 is located between the first edge 111 of the obverse surface 11 and the first point 13A of the intermediate surface 13, as viewed in the thickness direction z. With such a configuration, in a cross section orthogonal to the direction in which the first edge 111 extends, the intermediate surface 13 includes a plurality of sections that extend toward the second side in the thickness direction z between the first point 13A and the first edge 111. With such a configuration, separation between the conductor 10 and the sealing resin 40 is inhibited in multiple stages.

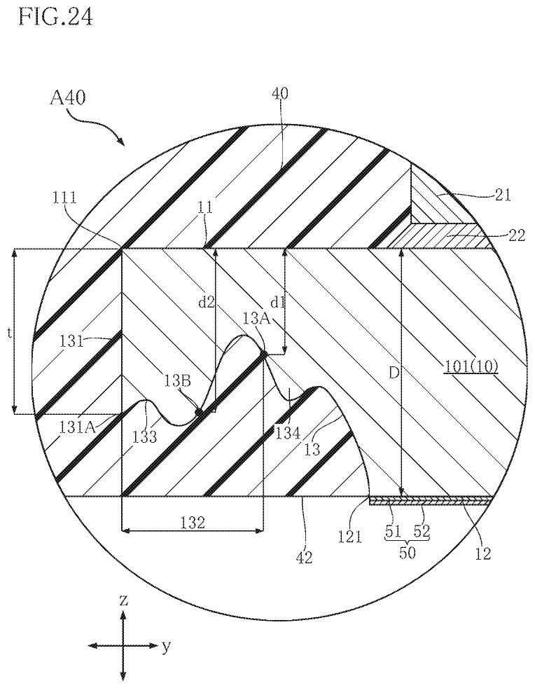

A semiconductor device A40 according to a fourth embodiment of the present disclosure is described below with reference to FIG. 24. In these figures, the elements that are identical or similar to those of the semiconductor device A10 described above are denoted by the same reference signs, and the descriptions thereof are omitted. Note that FIG. 24 is a sectional view that can be compared to the view of FIG. 7, which shows the semiconductor device A10.

The semiconductor device A40 differs from the semiconductor device A10 in configuration of the intermediate surface 13 of the conductor 10.

As shown in FIG. 24, the intermediate surface 13 includes a recess 133 and a projection 134. The configuration of the recess 133 is the same as that of the semiconductor device A30 described above. The projection 134 projects toward the second side in the thickness direction z. The projection 134 is located between the first point 13A of the intermediate surface 13 and the second edge 121 of the reverse surface 12, as viewed in the thickness direction z. The intermediate surface 13 may not include the recess 133 while including the projection 134.

Referring to FIG. 24, in the semiconductor device A40, the dimension t of the end 131 of the intermediate surface 13 in the thickness direction z may be smaller than the second distance d2 from the obverse surface 11 to the second point 13B of the intermediate surface 13 in the thickness direction z. Alternatively, the dimension t of the end 131 in the thickness direction z may be equal to or greater than the second distance d2.

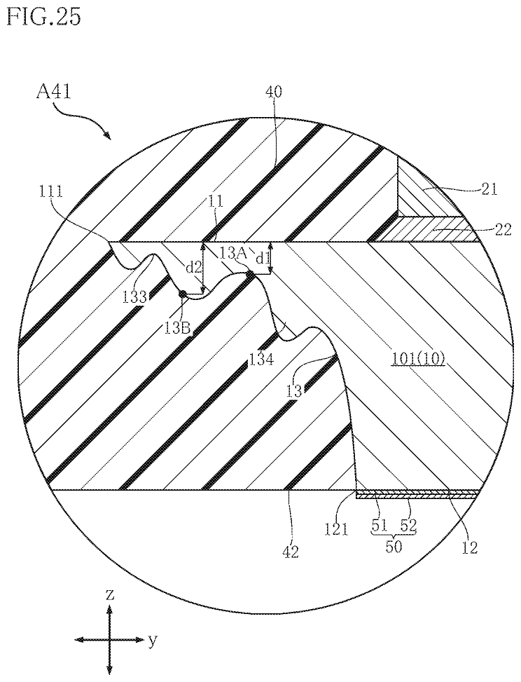

A semiconductor device A41 as a variation of the semiconductor device A40 is described below with reference to FIG. 25. Note that FIG. 25 is a sectional view that can be compared to the view of FIG. 24, which shows the semiconductor device A40.

As shown in FIG. 25, the semiconductor device A41 differs from the semiconductor device A40 in configuration of the intermediate surface 13 of the conductor 10. In the semiconductor device A41, the intermediate surface 13 does not include a distinct end 131 and a distinct overhang 132, while including a recess 133 and a projection 134. In a cross section orthogonal to the direction in which the first edge 111 of the obverse surface 11 extends, the portion of the conductor 10 defined by the obverse surface 11 and the section of the intermediate surface 13 from the first edge 111 to the first point 13A has an average thickness smaller than that of the corresponding portion of the semiconductor device A40. The semiconductor device A41 also satisfies the relationship that the first distance d1 from the obverse surface 11 to the first point 13A of the intermediate surface 13 in the thickness direction z is smaller than the second distance d2 from the obverse surface 11 to the second point 13B of the intermediate surface 13 in the thickness direction z.

The effects and advantages of the semiconductor device A40 are described below.

The semiconductor device A40 includes a conductor 10 that has an obverse surface 11 including a first edge 111, a reverse surface 12 including a second edge 121 and exposed from the sealing resin 40, and an intermediate surface 13 connected to the first edge 111 and the second edge 121. As viewed in the thickness direction z, the first edge 111 is located outward from the second edge 121. In a cross section orthogonal to the direction in which the first edge 111 of the obverse surface 11 extends, the intermediate surface 13 includes a first point 13A located between the first edge 111 and the second edge 121, and a second point 13B located between the first edge 111 and the first point 13A. The first distance d1 from the obverse surface 11 to the first point 13A in the thickness direction z is smaller than the second distance d2 from the obverse surface 11 to the second point 13B in the thickness direction z. Thus, the semiconductor device A40 also effectively eliminates or reduces the separation between the conductor 10 and the sealing resin 40.

In the semiconductor device A40, the intermediate surface 13 of the conductor 10 includes a recess 133 similar to that of the semiconductor device A30, and a projection 134 projecting toward the second side in the thickness direction z. The projection 134 is located between the first point 13A of the intermediate surface 13 and the second edge 121 of the reverse surface 12, as viewed in the thickness direction z. With such a configuration, in a cross section orthogonal to the direction in which the first edge 111 extends, the intermediate surface 13 includes sections that extend toward the second side in the thickness direction z between the first point 13A and the first edge 111. With such a configuration, separation between the conductor 10 and the sealing resin 40 is inhibited in a larger number of stages.

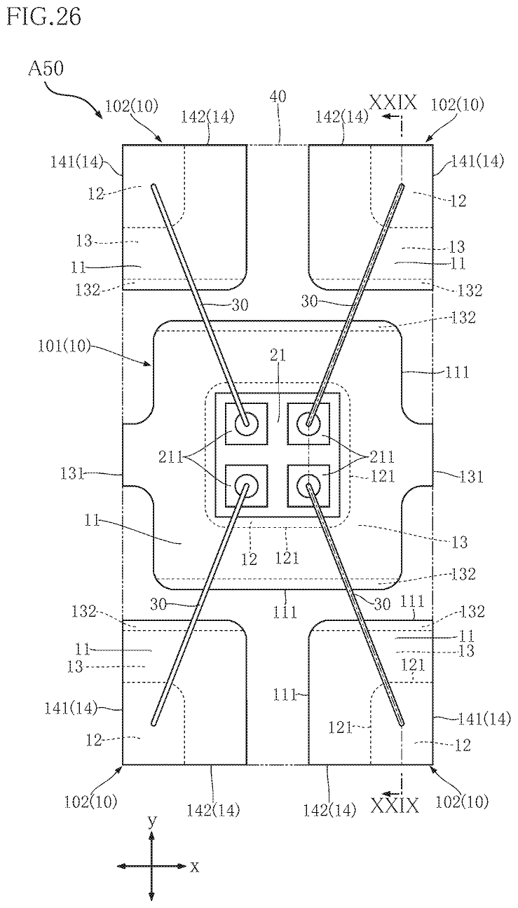

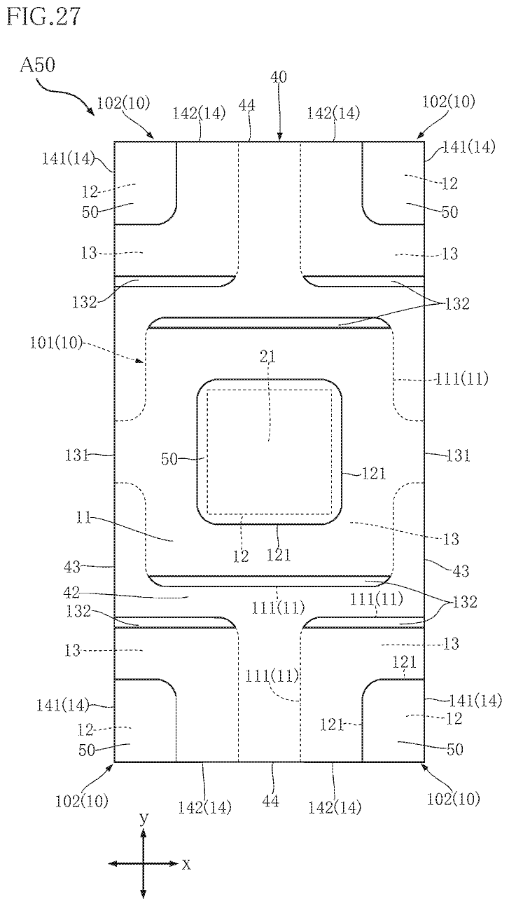

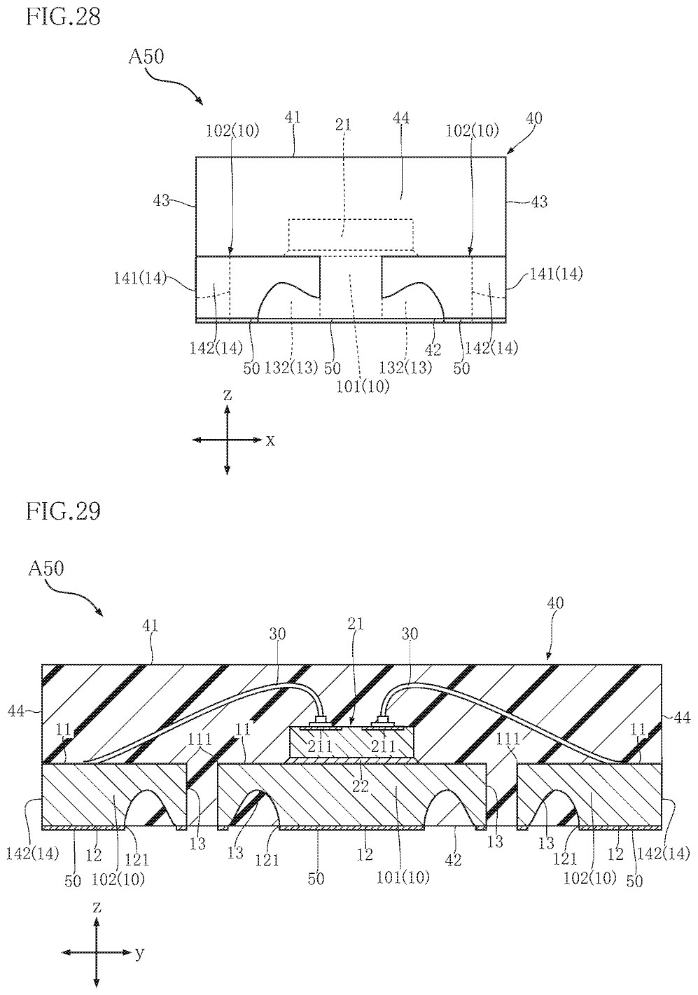

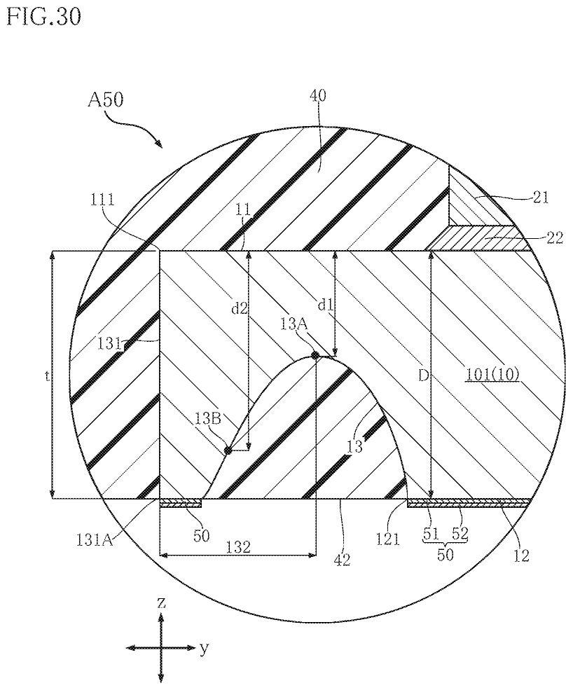

A semiconductor device A50 according to a fifth embodiment of the present disclosure is described below with reference to FIGS. 26 to 30. In these figures, the elements that are identical or similar to those of the semiconductor device A10 described above are denoted by the same reference signs, and the descriptions thereof are omitted.

The semiconductor device A50 differs from the semiconductor device A10 in configuration of the intermediate surface 13 of the conductor 10.

As shown in FIG. 30, the dimension t of the end 131 of the intermediate surface 13 in the thickness direction z is equal to or greater than the second distance d2 from the obverse surface 11 of the conductor 10 to the second point 13B of the intermediate surface 13. The dimension t of the end 131 in the thickness direction z is equal to the distance D from the obverse surface 11 to the reverse surface 12 of the conductor 10 in the thickness direction z.

As shown in FIGS. 26, 27 and 29, in the semiconductor device A30, a portion of the overhang 132 of the intermediate surface 13 is exposed at the bottom surface 42 of the sealing resin 40. The portion of the overhang 132 that is exposed from the sealing resin 40 extends along the first direction x. As shown in FIG. 30, the portion of the overhang 132 that is exposed from the sealing resin 40 is covered with the coating layer 50.

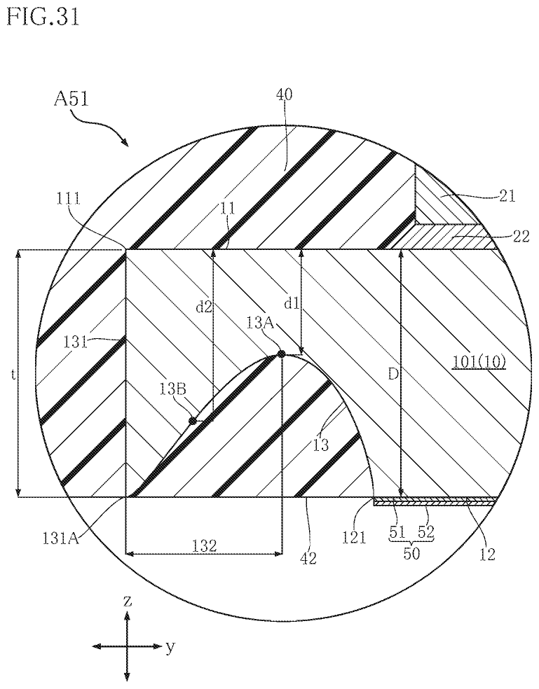

A semiconductor device A51 as a variation of the semiconductor device A50 is described below with reference to FIG. 31. Note that FIG. 31 is a sectional view that can be compared to the view of FIG. 30, which shows the semiconductor device A50.

As shown in FIG. 31, the semiconductor device A51 differs from the semiconductor device A50 in configuration of the intermediate surface 13 of the conductor 10. In the semiconductor device A51, the overhang 132 of the intermediate surface 13 does not include a portion exposed at the bottom surface 42 of the sealing resin 40. The entirety of the overhang 132 is covered with the sealing resin 40.

The effects and advantages of the semiconductor device A50 are described below.

The semiconductor device A50 includes a conductor 10 that has an obverse surface 11 including a first edge 111, a reverse surface 12 including a second edge 121 and exposed from the sealing resin 40, and an intermediate surface 13 connected to the first edge 111 and the second edge 121. As viewed in the thickness direction z, the first edge 111 is located outward from the second edge 121. In a cross section orthogonal to the direction in which the first edge 111 of the obverse surface 11 extends, the intermediate surface 13 includes a first point 13A located between the first edge 111 and the second edge 121, and a second point 13B located between the first edge 111 and the first point 13A. The first distance d1 from the obverse surface 11 to the first point 13A in the thickness direction z is smaller than the second distance d2 from the obverse surface 11 to the second point 13B in the thickness direction z. Thus, the semiconductor device A50 also effectively eliminates or reduces the separation between the conductor 10 and the sealing resin 40.

In the semiconductor device A50, the dimension t of the end 131 (the intermediate surface 13 of the conductor 10) in the thickness direction z is equal to the distance D from the obverse surface 11 to the reverse surface 12 of the conductor 10 in the thickness direction z. With such a configuration, in a cross section orthogonal to the direction in which the first edge 111 extends, the section that extends toward the second side in the thickness direction z between the first point 13A and the first edge 111 is longer than that in the semiconductor device A10. This contributes to effective elimination or reduction of the separation between the conductor 10 and the sealing resin 40. Also, the average thickness of the portion of the conductor 10 that is defined by the obverse surface 11 and the overhang 132 of the intermediate surface 13 is increased. This increases the flexural rigidity of the conductor 10, which eliminates or reduces the bending deformation of the conductor 10.

The present disclosure is not limited to the foregoing embodiments. The specific configuration of each part of the present disclosure can be varied in design in many ways.

The present disclosure includes the embodiments described in the following clauses.

### Clause 1

A semiconductor device comprising:
a conductor including an obverse surface including a first edge, a reverse surface spaced apart from the obverse surface in a thickness direction and including a second edge, and an intermediate surface connected to the first edge and the second edge;
a semiconductor element supported on the obverse surface and electrically connected to the conductor; and
a sealing resin that covers the obverse surface, the semiconductor element, and at least a portion of the intermediate surface, wherein
the reverse surface of the conductor is exposed from the sealing resin,
the first edge is located outward from the second edge as viewed in the thickness direction,
in a cross section orthogonal to the first edge, the intermediate surface includes a first point located between the first edge and the second edge and a second point located between the first edge and the first point, and
a first distance from the obverse surface to the first point in the thickness direction is smaller than a second distance from the obverse surface to the second point in the thickness direction.

### Clause 2

The semiconductor device according to clause 1, wherein the intermediate surface includes a recess that is recessed in the thickness direction, and
the recess is located between the first edge and the first point as viewed in the thickness direction.

### Clause 3

The semiconductor device according to clause 1 or 2, wherein the intermediate surface includes a projection that projects in the thickness direction, and
the projection is located between the first point and the second edge as viewed in the thickness direction.

### Clause 4

The semiconductor device according to any one of clauses 1 to 3, wherein the intermediate surface includes an end extending from the first edge in the thickness direction and an overhang, the end including a third edge opposite from the first edge in the thickness direction, the overhang extending from the third edge to the first point.

### Clause 5

The semiconductor device according to clause 4, wherein the dimension of the end in the thickness direction is equal to or greater than the second distance.

### Clause 6

The semiconductor device according to clause 4 or 5, wherein the dimension of the end in the thickness direction is smaller than a distance from the obverse surface to the reverse surface in the thickness direction.

### Clause 7

The semiconductor device according to clause 5, wherein the dimension of the end in the thickness direction is equal to a distance from the obverse surface to the reverse surface in the thickness direction.

### Clause 8

The semiconductor device according to clause 7, wherein a portion of the overhang is exposed from the sealing resin.

### Clause 9

The semiconductor device according to any one of clauses 4 to 8, wherein the end has a surface roughness greater than a surface roughness of the overhang.

### Clause 10

The semiconductor device according to any one of clauses 1 to 9, wherein the conductor includes a die pad and a terminal spaced apart from the die pad, and
the die pad includes a first obverse surface that forms a portion of the obverse surface of the conductor, whereas the terminal includes a second obverse surface that forms another portion of the obverse surface of the conductor,
the semiconductor element is supported on the first obverse surface of the die pad, and
the terminal is electrically connected to the semiconductor element.

### Clause 11

The semiconductor device according to clause 10, further comprising a wire bonded to the semiconductor element and the second obverse surface of the terminal, and
the wire is covered with the sealing resin.

### Clause 12

The semiconductor device according to clause 10 or 11, wherein the terminal includes a first reverse surface forming a portion of the reverse surface of the conductor, and a side surface connected to the second obverse surface and the first reverse surface, the side surface being exposed from the sealing resin.

### Clause 13

The semiconductor device according to clause 12, wherein the terminal includes an intermediate surface connected to the second obverse surface and the first reverse surface and at least partially covered with the sealing resin, the intermediate surface being connected to the side surface.

### Clause 14

The semiconductor device according to any one of clauses 1 to 9, further comprising a coating layer that covers the reverse surface of the conductor,
wherein the coating layer contains a metallic element.

### Clause 15

The semiconductor device according to clause 14, wherein the conductor includes a side surface connected to the obverse surface and the reverse surface and exposed from the sealing resin, the side surface being covered with the coating layer.

### Clause 16

The semiconductor device according to clause 14 or 15, wherein the metallic element includes at least one of nickel and palladium.

### REFERENCE NUMERALS

A10, A20, A30, A40, A50: Semiconductor device
10: Conductor 101: Die pad
102: Terminal 11: Obverse surface
111: First edge 12: Reverse surface
121: Second edge 13: Intermediate surface
13A: First point 13B: Second point
131: End 131A: Edge (Third edge)
132: Overhang 132A: First region
132B: Second region 133: Recess
134: Projection 14: Side surface
141: First surface 142: Second surface
21: Semiconductor element 211: Electrode
22: Bonding layer 30: Wire
40: Sealing resin 41: Top surface
42: Bottom surface 43: First side surface
44: Second side surface 50: Coating layer
51: First layer 52: Second layer
81: Substrate 811: Obverse surface
812: Reverse surface 813: First concave surface
814: Second concave surface 815: End surface
82: Bonding material 83: Sealing resin
881: First mask layer 881A: Opening
882: Second mask layer 883: Third mask layer
884: Fourth mask layer d1: First distance
d2: Second distance D: Distance
t: dimension CL: Cutting line
z: Thickness direction x: First direction y: Second direction

1. A semiconductor device comprising:
a conductor including an obverse surface including a first edge, a reverse surface spaced apart from the obverse surface in a thickness direction and including a second edge, and an intermediate surface connected to the first edge and the second edge;
a semiconductor element supported on the obverse surface and electrically connected to the conductor; and
a sealing resin that covers the obverse surface, the semiconductor element, and at least a portion of the intermediate surface, wherein
the reverse surface of the conductor is exposed from the sealing resin,
the first edge is located outward from the second edge as viewed in the thickness direction,
in a cross section orthogonal to the first edge, the intermediate surface includes a first point located between the first edge and the second edge and a second point located between the first edge and the first point, and
a first distance from the obverse surface to the first point in the thickness direction is smaller than a second distance from the obverse surface to the second point in the thickness direction.

2. The semiconductor device according to claim 1, wherein the intermediate surface includes a recess that is recessed toward one side in the thickness direction, and
the recess is located between the first edge and the first point as viewed in the thickness direction.

3. The semiconductor device according to claim 1, wherein the intermediate surface includes a projection that projects in the thickness direction, and
the projection is located between the first point and the second edge as viewed in the thickness direction.

4. The semiconductor device according to claim 1, wherein the intermediate surface includes an end extending from the first edge in the thickness direction and an overhang, the end including a third edge opposite from the first edge in the thickness direction, the overhang extending from the third edge to the first point.

5. The semiconductor device according to claim 4, wherein the dimension of the end in the thickness direction is equal to or greater than the second distance.

6. The semiconductor device according to claim 4, wherein the dimension of the end in the thickness direction is smaller than a distance from the obverse surface to the reverse surface in the thickness direction.

7. The semiconductor device according to claim 5, wherein the dimension of the end in the thickness direction is equal to a distance from the obverse surface to the reverse surface in the thickness direction.

8. The semiconductor device according to claim 7, wherein a portion of the overhang is exposed from the sealing resin.

9. The semiconductor device according to claim 4, wherein the end has a surface roughness greater than a surface roughness of the overhang.

10. The semiconductor device according to claim 1, wherein the conductor includes a die pad and a terminal spaced apart from the die pad, and
the die pad includes a first obverse surface that forms a portion of the obverse surface of the conductor, whereas the terminal includes a second obverse surface that forms another portion of the obverse surface of the conductor,
the semiconductor element is supported on the first obverse surface of the die pad, and
the terminal is electrically connected to the semiconductor element.

11. The semiconductor device according to claim 10, further comprising a wire bonded to the semiconductor element and the second obverse surface of the terminal, and
the wire is covered with the sealing resin.

12. The semiconductor device according to claim 10, wherein the terminal includes a first reverse surface forming a portion of the reverse surface of the conductor, and a side surface connected to the second obverse surface and the first reverse surface, the side surface being exposed from the sealing resin.

13. The semiconductor device according to claim 12, wherein the terminal includes an intermediate surface connected to the second obverse surface and the first reverse surface and at least partially covered with the sealing resin, the intermediate surface being connected to the side surface.

14. The semiconductor device according to claim 1, further comprising a coating layer that covers the reverse surface of the conductor,
wherein the coating layer contains a metallic element.

15. The semiconductor device according to claim 14, wherein the conductor includes a side surface connected to the obverse surface and the reverse surface and exposed from the sealing resin, the side surface being covered with the coating layer.

16. The semiconductor device according to claim 14, wherein the metallic element includes at least one of nickel and palladium.
